(19) United States
(12) Patent Application Publication
(10) Pub. No.: US 2017/0234937 A1
(43) Pub. Date: Aug. 17, 2017

(54) TEST APPARATUS FOR LIGHT EMITTING DEVICES

(71) Applicant: Samsung Electronics Co., Ltd., Suwon-si (KR)

(72) Inventors: Seung Won Park, Yongin-si (KR); Joon Sub Lee, Seoul (KR); Seung Won Kang, Anyang-si (KR)

(21) Appl. No.: 15/234,417

(22) Filed: Aug. 11, 2016

(30) Foreign Application Priority Data
Feb. 15, 2016 (KR) 10-2016-0017152

(51) Int. Cl. G01R 31/44; G01J 1/44

(52) U.S. Cl. CPC G01R 31/44; G01J 1/44; G01J 2001/4252

(57) ABSTRACT

A testing apparatus includes a plate unit including at least one chip mounting unit on which a light emitting diode (LED) to be tested is mounted. The chip mounting unit has a first region in which the LED is overlaid and a second region surrounding the first region. The first and second electrode pads are disposed in the first region and include respective extension portions extended toward the second region. A probe portion is configured to connect to the extension portions of the first and second electrode pads. A power control unit is configured to selectively apply test power to the LED through the probe portion. A light measuring unit is configured to measure light properties of light emitted by the LED.

### CROSS-REFERENCE TO RELATED APPLICATION

This application claims priority under 35 U.S.C. §119 from Korean Patent Application No. 10-2016-0017152 filed on Feb. 15, 2016, the disclosure of which is hereby incorporated by reference in its entirety.

### FIELD OF THE INVENTION

The present inventive concept relates to semiconductor component testing, and more specifically to testing a light emitting device.

### BACKGROUND

Semiconductor light emitting devices emit light using the principle of the recombination of electrons and holes when an electrical current is applied thereto. Due to various advantages, including low power consumption, high luminance, and miniaturization, semiconductor light emitting devices are widely used as light sources. In particular, with the development of nitride light emitting devices, the range of use thereof has been further extended, and thus, nitride light emitting devices have been employed in a broad range of products including for example, automobile headlights and general lighting devices.

Consequently, there is a demand for testing apparatuses to provide products with enhanced reliability when employing semiconductor light emitting devices as light sources.

### SUMMARY

An exemplary embodiment of the present inventive concepts is directed to a testing apparatus, which has improved accuracy in a light emitting diode (LED) chip test and is easy to implement.

An exemplary embodiment of the present inventive concepts is directed to a testing apparatus including a plate unit including at least one chip mounting unit on which an LED chip to be tested is mounted, having a first region in which the chip mounting unit is overlaid with the LED chip to be tested and a second region, a region of the chip mounting unit except for the first region, first and second electrode pads disposed in the first region of the at least one chip mounting unit and including extension portions extended toward the second region, respectively, a probe portion able to be connected to the extension portions of the first and second electrode pads, a power control unit configured to selectively apply test power to the LED chip to be tested, through the probe portion, and a light measuring unit configured to measure light properties of light emitted by the LED chip to be tested.

An exemplary embodiment of the present inventive concepts is directed to a testing apparatus including a plate unit including at least one chip mounting unit on which an LED chip to be tested is mounted, having a first region in which the chip mounting unit is overlaid with the LED chip to be tested and a second region, a region of the chip mounting unit except for the first region, first and second electrode pads disposed in the first region of the chip mounting unit and including portions extended toward the second region, respectively, first and second via electrodes electrically connected to the first and second electrode pads and penetrating through the chip mounting unit in a thickness direction to apply test power to the first and second electrode pads, a probe portion able to be connected to the first and second via electrodes, a power control unit configured to selectively control power applied to the probe portion, a power control unit configured to selectively apply test power to the LED chip to be tested through the probe portion, and a light measuring unit configured to measure light properties of light emitted by the LED chip to be tested.

An exemplary embodiment of the present inventive concepts is directed to a test apparatus comprising a movable plate configured to receive one or more test adaptors. Each test adaptor is configured to receive a respective light emitting diode (LED) by reducing a pressure between the respective test adaptor and a front surface of the LED opposing a photonic emitting surface of the LED. The test adaptor includes a pair of displaced electrode pads configured to contact a respective pair of device electrodes disposed on the front surface of the LED. A light measurement unit is configured to measure a photonic emission from the photonic emitting surface of a respective one of the LEDs to determine an optical property of the LED. The light measurement unit is positioned proximal to the photonic emitting surface of the LED. A power unit is configured to supply a current through a first probe and a second probe connected between the power unit and the respective displaced electrode pad.

### BRIEF DESCRIPTION OF THE DRAWINGS

These and/or other aspects and advantages of the present general inventive concepts will become apparent and more readily appreciated from the following description of the embodiments, taken in conjunction with the accompanying drawings of which:

FIG. 1 is a schematic view of a testing apparatus according to an example embodiment of the present inventive concept;

FIG. 2 is an exploded perspective view of the plate unit of FIG. 1;

FIG. 3 is a perspective view of the chip mounting unit of FIG. 2;

FIG. 4 is a cross-sectional view of the chip mounting unit in FIG. 3, taken along line I-I′;

FIG. 5 is an elevation view of another example embodiment of the chip mounting unit of FIG. 4;

FIG. 6 is a schematic view of another example embodiment of the testing apparatus of FIG. 1;

FIG. 7 is an elevation view of the chip mounting unit employed in the testing apparatus of FIG. 6; and

FIG. 8 is a cross-sectional view of the LED chip of FIG. 3, taken along line II-II′.

### DETAILED DESCRIPTION

Reference will now be made in detail to the embodiments of the present general inventive concepts, examples of which are illustrated in the accompanying drawings, wherein like reference numerals refer to the like elements throughout. The embodiments are described below in order to explain the present general inventive concepts by referring to the figures.

In a description of example embodiments of the present inventive concept, a Miller index expressed by three sets of integers is used as a notation describing a crystallographic plane or direction. A plurality of planes and directions having the same relative symmetry with respect to a crystallographic axis is equivalent in the crystallographic terms. In addition, a plane and direction having a given Miller index may move within a lattice by only a method of selecting a position and orientation of a unit cell. The equivalent planes and directions may be marked as a single family. Furthermore, a description of a family, for example, a single plane belonging to a crystal facet {100} may be equally applied to three equivalent planes (100), (010), and (001), as long as there is not a different description.

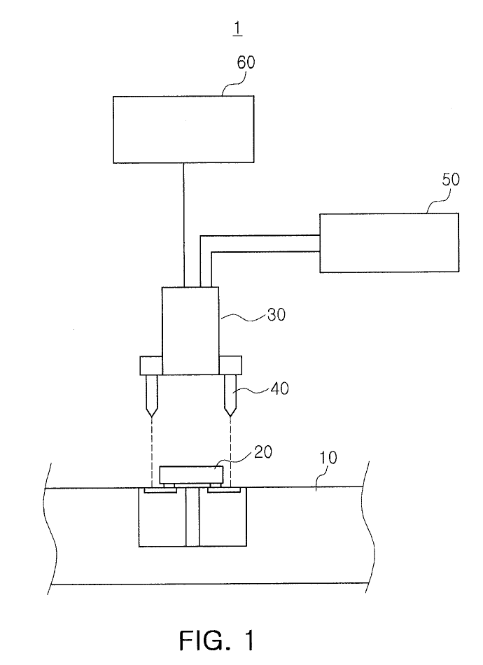

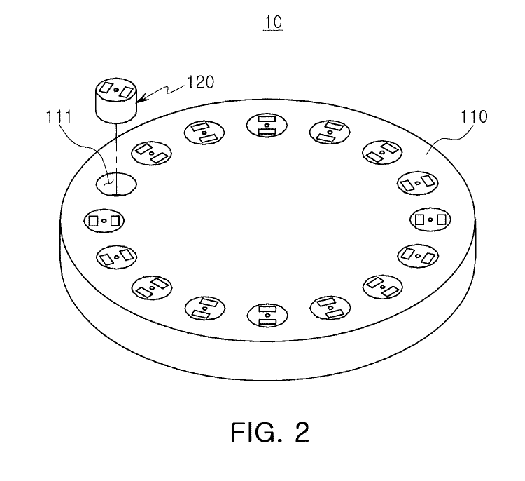

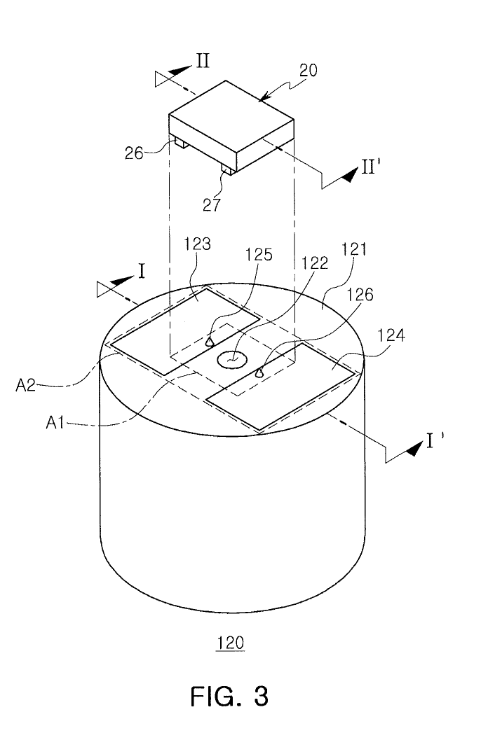

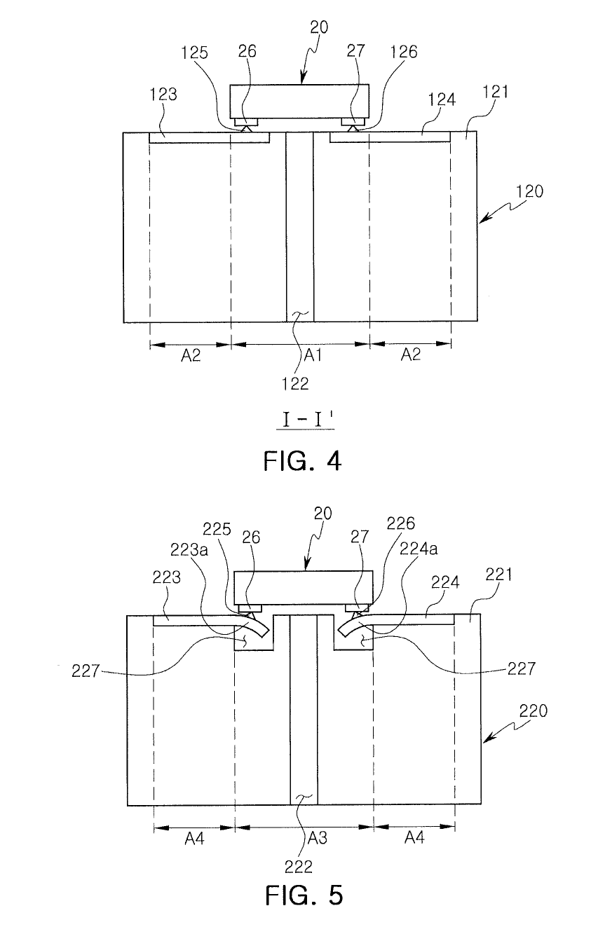

FIG. 1 is a schematic view of a testing apparatus according to an example embodiment of the present inventive concept. FIG. 2 is an exploded perspective view of the plate unit of FIG. 1. FIG. 3 is a perspective view of the chip mounting unit of FIG. 2. FIG. 4 is a cross-sectional view of the chip mounting unit in FIG. 3, taken along line I-I′.

With reference to FIG. 1, a testing apparatus 1 includes a plate unit 10 on which a light emitting diode (LED) chip (e.g. integrated circuit) 20 is disposed; a probe portion 40 applying power to the LED chip 20; a light measuring unit 30 measuring light properties of light emitted by the LED chip 20; and a power control unit 50 controlling power applied through the probe portion 40. In addition, the testing apparatus 1 may further include a light properties analysis unit 60 to analyze a value of light properties measured in the light measuring unit 30.

With reference to FIG. 2, the plate unit 10 may include a body portion 110 having a circular plate shape including at least two surfaces (e.g. referred to as “one surface” and the “other surface”). On an edge of the body portion 110, a plurality of connection recesses 111 in which a chip mounting unit 120 may be fixedly inserted may be disposed at equal intervals. The example embodiment describes an embodiment in which 16 connection recesses 111 may be disposed on the edge thereof, however the present inventive concept is not limited thereto. In another example embodiment, a single connection recess 111 may be disposed thereon. The plate unit 10 may be formed of a material such as metal or engineering plastics, having excellent durability, but is not limited thereto. Furthermore, various materials may be used for the plate unit 10 to match or optimize the thermal characteristics of the LED chip 20 during test, and to optimize the electrical connections between the respective LED chip 20 and the plate unit 10.

With reference to FIG. 2 and FIG. 3, the chip mounting unit 120 may include a plurality of electrode pads 123 and 124 in a base member 121 provided as a supporting portion on which the LED chip 20 to be tested is disposed. The base member 121 may be formed to have a size corresponding to the connection recess 111, thereby being fixedly inserted thereinto. In one example, a diameter of the base member 121 is slightly less than a diameter of the respective connection recesses 111, to allow the base member 121 to be inserted into the respective connection recess while minimizing mechanical movement of the base member 121. The base member 121 may be formed of a material such as metal or engineering plastics, having excellent durability, but is not limited thereto. In addition, the base member 121 may be formed of various materials in consideration of the thermal characteristics of the LED chip 20, and electrical connections between the base member 121 (as part of the chip mounting unit 120) and the plate unit 10.

The electrode pads 123 and 124 may be disposed on the base member 121 so that the LED chip 20 to be tested may be disposed in a flip chip manner on the chip mounting unit 120. The term “flip chip” as used herein refers to a semiconductor with connections (e.g. solder bumps or “electrodes” in one embodiment) on the same “active” surface as the active devices (e.g. diodes), with the substrate being on the opposing surface.

Specifically, the electrode pads 123 and 124 may have first and second polarities, respectively, when power is applied thereto. The first and second electrode pads 123 and 124 may be formed in such a manner that a conductive material including one or more of as Gold (Au), Silver (Ag), Copper (Cu), Zinc (Zn), Aluminum (Al), Indium (In), Titanium (Ti), Silicon (Si), Germanium (Ge), Tin (Sn), Magnesium (Mg), Tantalum (Ta), Chromium (Cr), Tungsten (W), Ruthenium (Ru), Rhodium (Rh), Iridium (Ir), Nickel (Ni), Palladium (Pd), and Platinum (Pt) is disposed as a single or multilayer structure on the base member 121. The first and second electrode pads 123 and 124 may be manufactured separately from, and subsequently attached to, the base member 121, but are not limited thereto. According to an example embodiment, the first and second electrode pads 123 and 124 may be manufactured separately from the base member 121, and then affixed to the base member 121 with a molding process.

With reference to FIG, 3, the first and second electrode pads 123 and 124 may include a first region A1 defined as a position in which the LED chip 20 is disposed, and a second region A2. The second region A2 is defined as a region of the chip mounting unit 120, where the probe portion 40 is connected to apply power to the respective LED, but excludes the A1 region. The first region A1 may be disposed in a central area of the base member 121, while the second region A2 may be disposed to surround the first region A1. The first and second electrode pads 123 and 124 may be disposed to have shapes substantially identical to each other.

The first region A1 may be a region in which the LED chip 20 may be disposed. In the first region A1, first and second electrodes 26 and 27 respectively of the LED chip 20 may be connected thereto, so that the LED chip 20 may be disposed in a flip chip manner on the first and second electrode pads 123 and 124 respectively. In an embodiment in which the first and second electrode pads 123 and 124 may not be disposed in the chip mounting unit 120, the LED chip 20 may be disposed in an “epi-up” configuration, in which the first and second electrodes 26 and 27 may be exposed upwardly, and power is applied directly to the first and second electrodes 26 and 27. The term “epi-up” refers to a flip chip device mounted with the active surface facing away (e.g. up) from the test platform. In contrast a flip chip device mounted in a “flip chip manner” refers to the active surface facing toward (e.g. down) the test platform. Light from the LED chip 20 mounted in a flip chip manner may be emitted in such a manner that light penetrates through a substrate (from the active side towards and through the substrate). Therefore, in an embodiment in which light output is tested with the LED chip 20 disposed in an epi-up configuration, the light output may represent significant differences in a luminous flux, or light distribution, from light properties of light emitted when the LED chip 20 is mounted in the final system to be used (e.g. an end-user system).

In an example embodiment, the LED chip 20 may be disposed in a flip chip manner on the chip mounting unit 120 to measure light properties, wherein the light properties are the same as those of light emitted after the LED chip 20 is mounted in the final system. Therefore, errors occurring when an amount of phosphor and a mixing ratio are adjusted (based on the test results and the desired LED performance) may be significantly reduced.

On a surface of the first region A1, at least two convex portions 125 and 126 may be formed to allow the LED chip 20 to be securely fixed thereto. In addition, the chip mounting unit 120 may further include a fixing means to fix the LED chip 20. Specifically, in the first region A1 in which the LED chip 20 is disposed, an inlet port 122 penetrating through the base member 121 in a direction perpendicular to the flip chip active surface thereof may be provided. The inlet port 122 is a through hole to apply a reduced pressure (e.g., a partial vacuum) to the LED chip 20. The inlet port 122 may remove air below a lower surface of the LED chip 20 to cause an air pressure difference between the LED chip 20 and the ambient pressure, thereby holding the LED chip 20 in the first region A1 of the chip mounting unit 120. However, the fixing means is not limited to the example embodiment, and various methods such as bonding using adhesive tape may be used.

The probe portion 40 may be connected to the first and second electrode pads 123 and 124 in the second region A2 to apply power thereto. The probe portion 40 may be configured to have a pair of probes in order to be connected to the first and second electrode pads 123 and 124, respectively. In addition, the probe portion 40 may be connected to the power control unit 50 to be capable of supplying a sufficient electrical current to operate the LED chip 20 according to a control signal of the power control unit 50. The probe portion 40 may be configured to descend to be connected to the second region A2 of the first and second electrode pads 123 and 124 after the LED chip 20 is disposed on the first and second electrode pads 123 and 124. In another embodiment, the plate unit is raised, so that the first and second electrode pads 123 and 124 make contact with the respective probe portions.

The light measuring unit 30 may be provided above the LED chip 20 to be capable of measuring light emitted by the LED chip 20. Furthermore, the light measuring unit 30 may further include a reflective portion reflecting light emitted by the LED chip 20 to a light measuring sensor. As illustrated in FIG. 1, the light measuring unit 30 may be configured to be integrated with the probe portion 40, but is not limited thereto. In addition, the light measuring unit 30 may be configured, separately from the probe portion 40. The light properties analysis unit 60 may analyze a luminous flux and light distribution based on a value measured in the light measuring unit 30, and may include a central processing unit and a program for analysis thereof

The LED chip 20 may have a configuration as illustrated in FIG. 8. A detailed description thereof will be described with reference to FIG. 8. The LED chip 20 may include a first surface C on which first and second electrodes are disposed, and a second surface D opposing the first surface C. The LED chip 20 may include a light transmissive substrate 21 and a light emitting structure 23 disposed on the light transmissive substrate 21. A surface of the light emitting structure 23 may be provided as the first surface C, and the first and second electrodes 26 and 27 respectively may be connected to the light emitting structure 23.

The substrate 21 may be a substrate for the growth of a semiconductor including a material such as Sapphire, SiC, MgAl₂O₄, MgO, LiAlO₂, LiGaO₂, or GaN. In this embodiment, Sapphire is a crystal having Hexa-Rhombo R3c symmetry, has lattice constants of 13.001 Å and 4.758 Å in directions of a c-axis and an a-axis, respectively, and includes a C (0001) plane, an A (11-20) plane, or an R (1-102) plane. In this embodiment, since a Nitride thin film may be relatively easily grown on the C plane, which is stable at relatively high temperatures, the C plane is commonly used for a Nitride growth substrate.

The substrate 21 may include surfaces opposing each other, and an unevenness structure may be formed on at least one of the opposing surfaces. The unevenness structure may be provided by etching a portion of the substrate 21 or by forming a hetero material layer different from the substrate 21.

As illustrated in FIG. 8, in an embodiment in which the unevenness structure is formed on a surface of the substrate provided as a growth surface for the light emitting structure 23, stress caused by a difference in lattice constants in an interface between the substrate 21 and a first conductive semiconductor layer 23a may be reduced. Specifically, in an embodiment in which a group III Nitride-based semiconductor layer is grown on a Sapphire substrate, a difference in lattice constants between the substrate and the group III Nitride-based compound semiconductor layer may cause a dislocation defect. The dislocation defect may propagate upwardly from the substrate, leading to deterioration in quality of a semiconductor layer crystal.

In the example embodiment, as the unevenness structure including convex portions is provided on the substrate 21, the first conductive semiconductor layer 23a is grown on sides of the convex portions, thereby preventing the dislocation defect from propagating upwardly from the substrate. Thus, a high-quality light emitting diode package may be provided, thereby increasing internal quantum efficiency.

In addition, since the unevenness structure may lead to a path of light emitted by an active layer 23b, being varied, a rate of light absorbed within a semiconductor layer may be decreased, and a light scattering rate may be increased, so that light extraction efficiency may be improved.

A thickness “tc” of the substrate 21 may be 100 μm or less, and specifically, 1 μm to 20 μm, but is not limited thereto. The range of thickness may be obtained by polishing a growth substrate for semiconductor growth. In detail, the growth substrate may be polished by grinding the second surface D or by a method of lapping in which the growth substrate is polished by a function of wear and grinding using a lap and lapping powder.

A buffer layer 22 may be interposed between the substrate 21 and the light emitting structure 23. In an embodiment where the light emitting structure 23 is grown on the substrate 21, for example, a GaN film is grown as a light emitting structure on a heterogeneous substrate, a lattice constant mismatch between the substrate and the GaN film may cause a lattice defect such as dislocation, and a difference in thermal expansion coefficients may lead to the substrate being warped, thus causing cracks in the light emitting structure. To control the occurrence of defects and warpage, the buffer layer 22 is formed on the substrate 21, and a light emitting structure having a required structure, such as a Nitride semiconductor, may be formed on the buffer layer 22. The buffer layer 22 may be a low-temperature buffer layer formed at a lower temperature than a temperature for the growth of a single crystal, but is not limited thereto.

As a material forming the buffer layer 22, AlₓIn_{y}Ga_{1-x-y}N (0≦x≦1, 0≦y≦1) may be used, and specifically, GaN, AlN, and AlGaN may be used. For example, the buffer layer may be formed of an undoped GaN layer formed at a predetermined thickness without being doped with impurities. A material forming the buffer layer 22 is not limited thereto. Thus, any structure improving an ability to crystallize the light emitting structure 23 may be employed, and a material such as ZrB₂, HfB₂, ZrN, HfN, TiN, or ZnO may also be used. In addition, the buffer layer 22 may also be used as a layer combining a plurality of layers or gradually changing a composition thereof.

The light emitting structure 23 may include the first conductive semiconductor layer 23a, the active layer 23b, and a second conductive semiconductor layer 23c, sequentially formed on one surface of the substrate 21. The first and second conductive semiconductor layers 23a and 23c may be N-type and P-type semiconductor layers respectively, and may include a Nitride semiconductor. Thus, in the example embodiment, it shoud be understood that the first and second conductive semiconductor layers 23a and 23c may refer to N-type and P-type Nitride semiconductor layers, respectively, but the first and second conductive semiconductor layers 23a and 23c are not limited thereto. The first and second conductive semiconductor layers 23a and 23c may include a material having empirical formula AlₓIn_{y}Ga_{(1-x-y)}N (0≦x≦1, 0≦y≦1, 0≦x+y≦1), such as GaN, AlGaN, or InGaN.

The active layer 23b may be a layer for emitting visible light (having a wavelength in a range of around 350 nm to around 680 nm), and may be configured of an undoped Nitride semiconductor layer having a structure of a single-quantum well (SQW) or a multi-quantum well (MQW). For example, the active layer 23b may be formed in a structure of a multi-quantum well in which a quantum barrier layer and a quantum well layer, having empirical formula AlₓIn_{y}Ga_{(1-x-y)}N (0≦x≦1, 0≦y≦1, 0≦x+y≦1), are alternately stacked, thus using a structure having a determined band gap. The quantum well recombines an electron and a hole, thereby emitting light. For example, in an embodiment of the multi-quantum well structure, an InGaN/GaN structure may be used. The first and second conductive semiconductor layers 23a and 23c and the active layer 23b may be formed using a crystal growth process such as metal organic chemical vapor deposition (MOCVD), molecular beam epitaxy (MBE), or Hydride vapor phase epitaxy (HYPE).

The first and second electrodes 26 and 27 are provided to supply power to the first and second conductive semiconductor layers 23a and 23c respectively, and may be provided to be connected to the first and second conductive semiconductor layers 23a and 230, respectively.

The first and second electrodes 26 and 27 may include a conductive material as a single or multilayer structure, having ohmic characteristics with respect to the first and second conductive semiconductor layers 23a and 23c. For example, the first and second electrodes 26 and 27 may be formed by depositing one or more materials amongst Au, Ag, Cu, Zn, Al, In, Ti, Si, Ge, Sn, Mg, Ta, Cr, W, Ru, Rh, Ir, Ni, Pd, Pt, or a Transparent Conductive Oxide (TCO), using a deposition method such as sputtering. The first and second electrodes 26 and 27 may be disposed in the same direction to oppose the substrate 21, based on the light emitting structure 23. Thus, the LED chip 20 may be flip-chip or eutectic bonded to a mounting surface thereof. In this embodiment, light emitted by the active layer 23b may be emitted externally via the substrate 21. In addition, according to an example embodiment, for light not reflected in the first and second electrodes 26 and 27 to be able to be reflected, a lower reflective layer 28 may be disposed to cover a region of the light emitting structure 23, except for a region thereof in which the first and second electrodes 26 and 27 are disposed.

Another example embodiment of the described chip mounting unit 120 will now be described. A description overlapping the description of the foregoing example embodiment will be omitted. FIG. 5 is an elevation view of another example embodiment of the chip mounting unit illustrated in FIG. 4. Similar to the chip mounting unit 120, a chip mounting unit 220 of another example embodiment may include first and second electrode pads 223 and 224 in a base member 221 provided as a supporting portion on which an LED chip 20, (an electronic element), is disposed. The base member 221 may have a size corresponding to the connection recess 111 of the plate unit 10, and may be formed of a material such as metal or engineering plastics, having excellent durability to endure multiple insertions of the chip mounting unit into the connection recesses without undo wear. In contrast to the chip mounting unit 120 described in FIG. 4, the chip mounting unit 220 may have a groove portion 227 formed in a lower portion of a first region A3 of the first and second electrode pads 223 and 224. Due to the presence of the groove portion 227, the first and second electrode pads 223 and 224 are now supported by the base member 221 in the second region A4. The electrode pads 223 and 224 have corresponding contact portions 223a and 224a respectively, in the groove portion 227, (in the first region A3). The contact portions 223a and 224a will elastically deform when pressed against corresponding first and second electrodes 26 and 27 (through the corresponding convexed portions 225 and 226), thus applying additional force against the first and second electrodes 26 to improve contact adhesion between the electrode pads and the chip electrodes.

Similar to the chip mounting unit 120, the chip mounting unit 220 may include a fixing means to fix the LED chip 20 to the chip mounting unit 220. Specifically, an inlet port 222 penetrating through the base member 221 in a direction perpendicular to first or second surface of the LED chip (see FIG. 8), thereof may be disposed in the first region A3 in which the LED chip 20 is provided. As a result of the testing apparatus 1 having the ability to measure the light properties of a flip-chip LED chip, the testing apparatus 1 may significantly reduce equipment costs and improve accuracy of test.

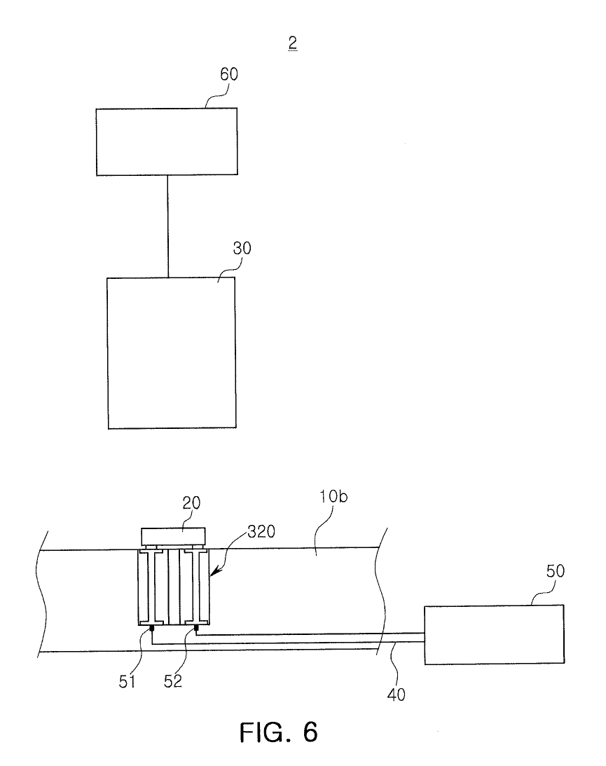

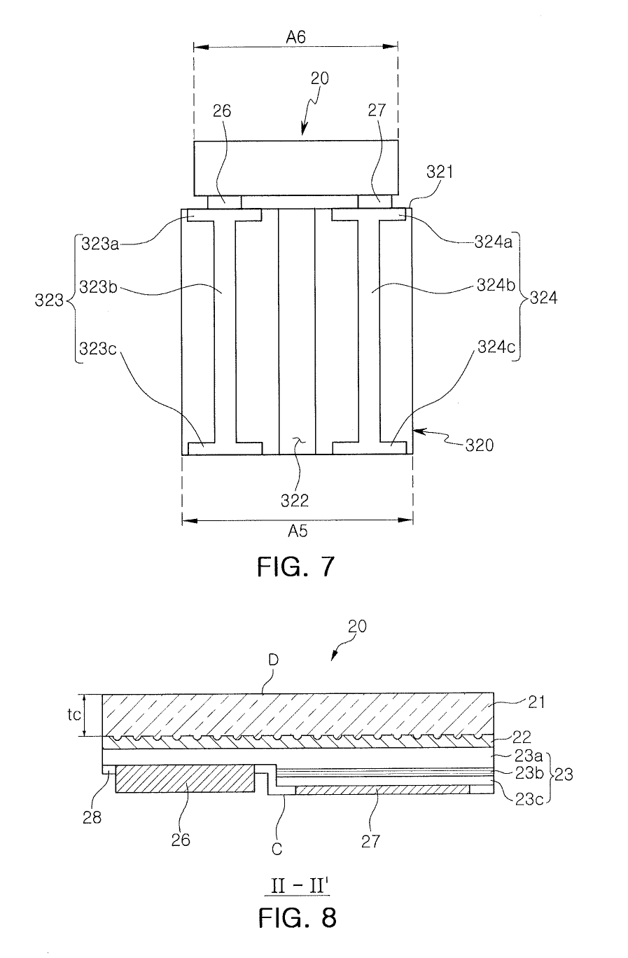

With reference to FIG. 6 and FIG. 7, a testing apparatus 2 of another example embodiment will be described. A description of elements common to the testing apparatus 1 of FIG. 1 will be omitted for brevity. FIG. 6 is a variation to the embodiment of the testing apparatus illustrated in FIG. 1. FIG. 7 is an elevation view of the chip mounting unit employed in the testing apparatus of FIG. 6. With reference to FIG. 6, the testing apparatus 2 according to another example embodiment may include a plate unit 10b in which an LED chip 20 is disposed; a probe portion 40 applying power to the LED chip 20; a light measuring unit 30 measuring light properties of light emitted by the LED chip 20; and a power control unit 50 controlling power applied to the probe portion 40. Furthermore, the testing apparatus 2 may further include a light properties analysis unit 60 analyzing a value of light properties measured in the light measuring unit 30.

In contrast to the testing apparatus 1 of FIG. 1, the testing apparatus 2 has the probe portion 40 applying power through a lower portion of a chip mounting unit 320. The chip mounting unit 320 may include first and second via electrodes 323b and 324b to supply power applied through the lower portion thereof to first and second electrode pads 323a and 324a in an upper portion of the chip mounting unit 320. Furthermore, the chip mounting unit 320 may include an inlet port 322 penetrating through the base member 321 in a direction perpendicular to first or second surface of the LED chip (see FIG. 8).

Specifically, as illustrated in FIG. 6, the chip mounting unit 320 may receive an electrical current from the power control unit 50 through first and second terminals 51 and 52 embedded in the plate unit 10b. In addition, as illustrated in FIG. 7, the chip mounting unit 320 may include first and second electrode structures 323 and 324.

In the first and second electrode structures 323 and 324, the respective first and second via electrodes 323b and 324b spanning from one surface to the other surface of a base member 321 (on which the LED chip 20 is mounted) the first and second electrode pads 323a and 324a disposed on one surface and the first and second connection pads 323c and 324c, respectively, disposed on the other surface in which both ends of the first and second via electrodes 323b and 324b are exposed may be formed to allow both surfaces of the base member 321 to be electrically connected to each other. The first and second via electrodes 323b and 324b, the first and second electrode pads 323a and 324a, and the first and second connection pads 323c and 324c may be formed in such a manner that a conductive material including one or more of Au, Ag, Cu, Zn, Al, In, Ti, Si, Ge, Sn, Mg, Ta, Cr, W, Ru, Rh, Ir, Ni, Pd, and Pt is disposed as a single or multilayer structure.

Thus, the chip mounting unit 320 may apply the electrical current applied to the first and second connection pads 323c and 324c to the first and second electrode pads 323a and 324a, through the respective first and second terminals 51 and 52. In the example embodiment, because the probe portion 40 may be connected through the first and second connection pads 323c and 324c, the additional region in the first and second electrode pads 323a and 324a to allow the probe portion 40 to be disposed may not be needed. Therefore, a width A5 of the chip mounting unit 320 may have substantially the same width as a width A6 of the LED chip 20. Thus, compared to the chip mounting unit 120 or 220, the relatively small-sized chip mounting unit 320 may be formed, and a relatively large number of chip mounting units may be disposed in the plate unit 10 having the same area. Accordingly, testing cost is reduced by enabling more LEDs to be testing concurrently. As set forth above, according to example embodiments of the present inventive concept, a testing apparatus which has improved accuracy in a light emitting diode (LED) chip test and is easy to implement is provided.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A test apparatus, comprising:
a plate unit including at least one chip mounting unit on which a light emitting diode (LED) chip to be tested is mounted, the chip mounting unit having a first region in which the LED chip is overlaid and a second region surrounding the first region;
a first electrode pad and a second electrode pad disposed in the first region and including respective extension portions extended toward the second region;
a probe portion configured to connect to the extension portions of the first and second electrode pads;
a power control unit configured to selectively apply test power to the LED chip through the probe portion; and
a light measuring unit configured to measure light properties of light emitted by the LED chip.

2. The test apparatus of claim 1, wherein the first and second electrode pads have substantially the same shape.

3. The test apparatus of claim 1, wherein the at least one chip mounting unit is fixedly inserted into a connection recess disposed on an edge of the plate unit.

4. The test apparatus of claim 1, wherein the first region includes a convex portion disposed thereon.

5. The test apparatus of claim 1, wherein the at least one chip mounting unit includes an elastic material layer on the first region to improve adhesion of the first region to the LED chip.

6. The test apparatus of claim 1, wherein the first region includes an inlet vacuum port passing through the at least one chip mounting unit in a direction perpendicular to a width of the LED chip.

7. The test apparatus of claim 1, wherein the first region is disposed in a region where the LED chip is disposed, and the second region is disposed on an edge of the at least one chip mounting unit.

8. The test apparatus of claim 1, wherein the LED chip is disposed in the first region with electrical connections of the LED chip proximally located to the first region.

9. A test apparatus device, comprising:
a plate unit including at least one chip mounting unit on which a light emitting diode (LED) chip to be tested is mounted, having a first region in which the LED chip is overlaid and a second region surrounding the first region;
a first electrode pad and a second electrode pad disposed in the first region and including respective portions extended toward the second region;
a first via electrode and a second via electrode electrically connected to the first and second electrode pads respectively, and passing through the at least one chip mounting unit in a direction perpendicular to a width of the LED chip to apply test power to the first and second electrode pads;
a probe portion configured to connect to the first and second via electrodes;
a power control unit configured to selectively control power applied to the probe portion;
a power control unit configured to selectively apply test power to the LED through the probe portion; and
a light measuring unit configured to measure light properties of light emitted by the LED chip.

10. The test apparatus of claim 9, wherein the at least one chip mounting unit is fixedly inserted into a connection recess disposed on an edge of the plate unit.

11. The test apparatus of claim 10, further comprising first and second connection terminals on a lower surface of the connection recess, connected to the respective first and second via electrodes to supply power applied by the power control unit.

12. The test apparatus of claim 10, wherein in the at least one chip mounting unit, first and second connection pads are further disposed on a surface in contact with the respective first and second connection terminals.

13. The test apparatus of claim 9, wherein the first electrode pad is electrically isolated from the second electrode pad.

14. The test apparatus of claim 9, wherein in the first region an inlet port passes through the at least one chip mounting unit in a direction perpendicular to a width of the LED chip.

15. The test apparatus of claim 9, wherein the LED chip is disposed in the first region with electrical connections of the LED chip proximally located to the first region.

16. A test apparatus comprising:
a movable plate configured to receive one or more test adaptors, each test adaptor configured to receive a respective light emitting diode (LED) by reducing a pressure between the respective test adaptor and a front surface of the LED opposing a photonic emitting surface of the LED, the test adaptor including a pair of displaced electrode pads configured to contact a respective pair of device electrodes disposed on the front surface of the LED;
a light measurement unit configured to measure a photonic emission from the photonic emitting surface of a respective one of the LEDs to determine an optical property of the LED, the light measurement unit positioned proximal to the photonic emitting surface of the LED; and
a power unit configured to supply a current to the LED through a first probe and a second probe connected between the power unit and the respective displaced electrode pad.

17. The test apparatus of claim 16 wherein the electrode pads are laterally displaced from the LED, collinear with the front surface of the LED, and the light measurement unit is disposed between the first probe and the second probe.

18. The test apparatus of claim 17 wherein each of the electrode pads include an elastically deformable cantilever portion in contact with the respective device electrode of the LED.

19. The test apparatus of claim 16 wherein the electrode pads are vertically displaced from the LED, perpendicular from the front surface of the LED, and the first probe and the second probe contact the electrode pads on a surface of the movable plate opposing a test surface proximal to the LED.

20. The test apparatus of claim 16 wherein the movable plate is a rotatable plate comprising a plurality of test adaptors circumferentially disposed thereon.
